(19) United States
(12) Patent Application Publication
(10) Pub. No.: US 2025/0201676 A1
(43) Pub. Date: Jun. 19, 2025

(54) SEMICONDUCTOR DEVICE AND METHOD FOR FABRICATING THE SAME

(71) Applicant: Infineon Technologies AG, Neubiberg (DE)

(72) Inventor: Achim Althaus, Regensburg (DE)

(21) Appl. No.: 18/975,455

(22) Filed: Dec. 10, 2024

(30) Foreign Application Priority Data
Dec. 19, 2023 (DE) 102023212987.6

(51) Int. Cl. H01L 23/495; H01L 21/48; H01L 21/56; H01L 23/00; H01L 23/31

(52) U.S. Cl. CPC H01L 23/49548; H01L 21/4842; H01L 21/565; H01L 23/3121; H01L 23/49513; H01L 23/4952; H01L 23/49562; H01L 24/48; H01L 2224/48248; H01L 2924/15153

(57) ABSTRACT

A semiconductor device is disclosed. The semiconductor device includes a chip carrier having a first cavity and a second cavity. A semiconductor die is mounted in the first cavity. The semiconductor die includes a patterned top metallization layer having a first electrical contact pad. An insulating layer is arranged inside the second cavity. A first end of a first electrical conductor is arranged over the insulating layer and a second end of the first electrical conductor is arranged on the first electrical contact pad of the semiconductor die. An encapsulant encapsulates the semiconductor die, both ends of the first electrical conductor, and parts of the chip carrier. A method for manufacturing the semiconductor device is also disclosed.

### TECHNICAL FIELD

The present disclosure relates to semiconductor devices, in particular to semiconductor devices for embedding into a printed circuit board (PCB).

### BACKGROUND

Modern power electronics for inverter controls, DC-DC converters and battery management are among the key technologies in electrified drives. The demands placed on applications in terms of power density, energy efficiency, reliability and system cost reduction are continuously increasing. One way of addressing these demands is to embed power semiconductors in power circuit boards. The power semiconductors are no longer soldered onto a printed circuit board as discretely packaged components, but embedded in a so-called system printed circuit board (power and logic) using chip embedding technology. For chip embedding, the semiconductor devices are usually provided without any protective layer or encapsulation at the contact pads which chip carrier complicates the handling of the semiconductor device during chip embedding.

There is thus a need for more robust power semiconductors for chip embedding into a PCB.

### SUMMARY

A semiconductor device is disclosed comprising a chip carrier comprising a first cavity and a second cavity. A semiconductor die is mounted in the first cavity, wherein the semiconductor die comprises a patterned top metallization layer comprising a first electrical contact pad. An insulating layer is arranged inside the second cavity. A first electrical conductor comprises a first end and a second end, wherein the first end of the first electrical conductor is arranged over the insulating layer and the second end of the first electrical conductor is electrically coupled to the first electrical contact pad of the semiconductor die. An encapsulant encapsulates the semiconductor die, both ends of the first electrical conductor and parts of the chip carrier.

A semiconductor device is disclosed comprising a chip carrier comprising a first cavity. A semiconductor die is mounted inside the first cavity, wherein the semiconductor die comprises a patterned top metallization layer including a first electrical contact pad and a contact pad. A first electrical conductor, wherein a first end of the first electrical conductor is fixed on the floating contact of the semiconductor die and a second end of the first electrical conductor is electrically coupled to the first electrical contact pad of the semiconductor die. An encapsulant encapsulates the semiconductor die and both ends of the first electrical conductor and wherein the first electrical conductor is partially exposed from a top surface of the encapsulant.

A method is disclosed for manufacturing a semiconductor device, the method comprising: providing a chip carrier; forming a first cavity and a second cavity on a surface of the chip carrier; mounting a semiconductor die in the first cavity, wherein the semiconductor die comprises a patterned top metallization layer comprising a first electrical contact pad; arranging an insulating layer inside the second cavity; mounting a first electrical conductor comprising a first end and a second end, wherein the first end of the first electrical conductor is mounted over the insulating layer and the second end of the first electrical conductor is mounted on the first electrical contact pad of the semiconductor die; and encapsulating the semiconductor die and both ends of the first electrical conductor by an encapsulant.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a top view of a semiconductor device with a chip carrier providing separate cavities for a semiconductor die and for a contact pad.

FIG. 2 illustrates a cross-sectional view of the semiconductor device along line AA′ of FIG. 1.

FIG. 3 illustrates a top view of an alternative example of a semiconductor device with a plurality of electrical conductors over one of the cavities.

FIG. 4 illustrates an example of an alternative semiconductor device with two cavities used for mounting the electrical conductors.

FIG. 5 illustrates an example of a top view of an alternative semiconductor device with a further cavity on the chip carrier.

FIG. 6 illustrates an example of a top view of an alternative semiconductor device with a contact pad on a semiconductor die.

FIG. 7A-7F illustrate a method of forming a semiconductor device with an exposed electrical conductor.

### DETAILED DESCRIPTION

The semiconductor device described herein comprises a chip carrier with a surface and cavities formed on the surface of the chip carrier. A semiconductor die is mounted inside one of the cavities and a contact pad is formed inside the other cavity. The contact pad is electrically isolated form the chip carrier. The semiconductor die and the contact pad are electrically coupled via an electrical conductor, in particular one end of the electrical conductor is electrically coupled to the semiconductor die and another end of the electrical conductor is fixed on the contact pad. The semiconductor die, parts of the chip carrier, and both ends of the electrical conductor are encapsulated by an encapsulant. The electrical conductor is exposed from the encapsulant in a direction vertical to the surface of the chip carrier and the exposed section of the electrical conductor is used as an external contact for the semiconductor device.

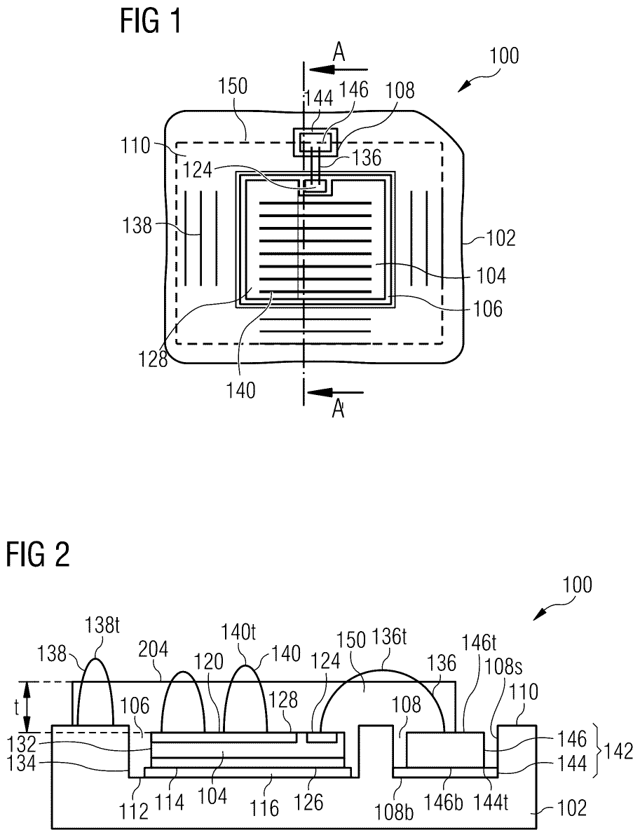

In FIG. 1 and FIG. 2, a top view and a cross-sectional view of an exemplary semiconductor device 100 are illustrated respectively. The cross-sectional view of the semiconductor device 100 in FIG. 2 shown the cross section along line AA′ of FIG. 1. The semiconductor device 100 has a chip carrier 102 and a semiconductor die 104. The chip carrier 102 may be a single piece i.e., comprises one continuous metal piece e.g., a leadframe made of a metal e.g., copper, copper-alloy, or iron-nickel alloy like alloy 42. There are at least two cavities 106, 108 formed on a surface 110 of the chip carrier 102, e.g., by stamping, coining or any other suitable technique. A bottom of the cavity 106 forms a die pad 112. The semiconductor die 104 is mounted inside the cavity 106 and on the die pad 112, wherein a lower side 114 (e.g. a backside) of the semiconductor die 104 faces die pad 112. An electrically conductive joint 116 is arranged between the lower side 114 of the semiconductor die 104 and the die pad 112, which electrically and mechanically couples the semiconductor die 104 to the chip carrier 102.

The semiconductor die 104 has a control pad 124 and load pads 126, 128 which are coupled with a control electrode and load electrodes of the semiconductor die 104 respectively. The load electrodes may be a source and drain electrode or an emitter and collector electrode. Each electrode (the control and the load electrodes) is formed via a respective stack of patterned metallization layers in the semiconductor die. The stack of patterned metallization layers may comprise a titanium layer arranged on a semiconductor material of the semiconductor die 104 and an NiV layer arranged on the titanium layer. An outermost patterned metallization layer of the respective stack of the patterned metallization layers forms the respective electrical contact pads 124, 126, 128. The control pad 124 and the load pad 128 may be formed on an upper side 120 (e.g. a frontside) of the semiconductor die 104 opposite to the lower side 114, whereas the load pad 126 may be formed on the lower side 114 of the semiconductor die 104. In FIGS. 1 and 2 the load pads 126, 128 are shown on opposite sides 114, 120 of the semiconductor die 104 as it is often implemented for vertical semiconductor devices.

However, in some examples, both load pads 126, 128 may be formed on upper side 120 of the semiconductor die 104 and the semiconductor die 104 experiences a current flow in a direction lateral to upper side 120 or lower side 114 of the semiconductor die 104 i.e., the semiconductor die 104 may be a planar semiconductor die.

The semiconductor die 104 comprises sidewalls 132 connecting the upper 120 and the lower 114 sides of the semiconductor die 104. The semiconductor die 104 is arranged inside the cavity 106 such that there is a gap between the sidewalls 134 of the cavity 106 and sidewalls 132 of the semiconductor die 104 to electrically isolate the upper side 120 of the semiconductor die 104 from the chip carrier 102.

The semiconductor device 100 has electrical conductors 136, 138, 140 which are realized as bond loops in the example shown in FIGS. 1 and 2. In detail, both ends of the electrical conductor 138 are electrically coupled to the surface 110 of the chip carrier 102 and therefore electrically coupled to the load pad 126 of the semiconductor die 104 and whereas, both ends of the electrical conductor 140 are electrically coupled to the load pad 128 of the semiconductor die 104. There can be any suitable number of the electrical conductor 138, 140 in the semiconductor device 100. The electrical conductors 138, 140 may also be bond ribbons or small clips.

In view of thermal performances, the control pad 124 is usually kept as small as possible in order to provide more space for the load pad 128. The control pad 124 is thus too small to form a closed bond loop on the control pad 124. To overcome this problem, one end of the electrical conductor 136 is arranged over the cavity 108 whilst another end of the electrical conductor 136 is electrically coupled to the control pad 124 of the semiconductor die 104. In particular, one end of the electrical conductor 136 is electrically coupled to a contact pad 142 inside the cavity 108, wherein the contact pad 142 is electrically isolated from the chip carrier 102.

The contact pad 142 has an insulating layer 144 and an electrically conductive structure 146. The insulating layer 144 is arranged between a base 146b of the electrically conductive structure 146 and a bottom 108b of the cavity 108. The insulating layer 144 completely covers the base 146b of the electrically conductive structure 146 and a part of the bottom 108b of the cavity 108 facing the base 146b of the electrically conductive structure 146. In some examples, the insulating layer may completely cover the bottom 108b of the cavity 108 and partially cover sidewalls 108s of the cavity 108. The insulating layer 144 may comprise a laminate, or ceramic or any suitable electrically insulating material. The base 146b of the electrically conductive structure 146 is fixed in a middle of a top surface 144t the insulating layer 144 such that sidewalls 108s of the cavity 108 are electrically isolated from the electrically conductive structure 146. The top surface 144t of the insulating layer faces away from the bottom 108b of the cavity 108. The middle of the top surface 144t of the insulating layer 144 is defined as a section of the insulating layer 144 away from lateral edges of the insulating layer 144. In particular, one end of the electrical conductor 136 is fixed to a top 146t of the electrically conductive structure 146 opposite to the base 146b. The electrically conductive structure 146 may be a metal block or a metal foil.

The ends of the electrical conductors 136, 138, 140 are electrically coupled to or fixed on their respective positions by e.g., ball bonding technique or a wedge bonding or soldering or sintering or welding.

An encapsulant 150 encapsulates the semiconductor die 104, both ends of the electrical conductors 136, 138, 140 and at least parts of the chip carrier 102. The encapsulant 150 also fills the gap between the sidewalls 132 of the semiconductor die 104 and the sidewalls 134 of the cavity 106. Similarly, the encapsulant 150 may fill at least parts of the gap between the sidewalls 108s of the cavity 108 and the electrically conductive structure 146. The middle section 136t, 138t, 140t of the electrical conductors 136, 138, 140 protrudes from an upper surface 204 of the encapsulant 150 and can thus be contacted after embedding the semiconductor die 104 into for instance a PCB (explained later). The middle section 136t, 138t, 140t of the electrical conductors 136, 138, 140 is between ends of the respective electrical conductors 136, 138, 140 and the upper surface 204 of the encapsulant 150 faces the surface 110 of the chip carrier 102. The cavity 108 may be partially exposed from the encapsulant 150, in particular the top 146t of the electrically conductive structure 146 is partially exposed and the exposed part of the electrically conductive structure 146 may be used to test the semiconductor die 104.

As described herein above, the semiconductor device 100 may be embedded into a PCB, wherein vias or holes are drilled above the middle section of 136t, 138t, 140t of the electrical conductors 136, 138, 140 136, 138, 140 and a metallization layer is arranged on a surface of the PCB. The metallization layer is electrically coupled to the respective middle section of 136t, 138t, 140t of the electrical conductor 136, 138, 140 136, 138, 140 by extending the metallization layer into holes or vias of the PCB.

The semiconductor device 100 may be embedded into a PCB which comprises multiple insulation layers alternating with metal layers for current rerouting. An insulation layer covering the semiconductor device's surface comprises vias or holes drilled above the middle section 136t, 138t, 140t of the electrical conductors 136, 138, 140 136, 138, 140 and is filled with a conducting material to contact the semiconductor device and integrate the device into a desired application circuit.

The encapsulant 150 has no filler particles and therefore may have a thickness t in a range of 70 μm to 100 μm wherein the thickness t of the encapsulant 150 is measured between the first control pad 124 of the semiconductor die 104 and the upper surface 204 of the encapsulant 150 in a direction vertical to the control pad 124 of the semiconductor die 104. The encapsulant 150 may comprise any suitable dielectric material in particular mold material with high-temperature stability and/or good dielectric properties. The thickness t of the encapsulant 150 in the above-described range leads to a smaller footprint of the semiconductor device 100.

In some examples, it is also possible that the encapsulant 150 completely encapsulates the surface 110 of the chip carrier 102 including the cavities 106, 108 and also further surfaces of the chip carrier 102.

In some examples, the contact pad 142 may be formed by a stack of an upper metal layer, a dielectric and a lower metal layer e.g., a direct copper bonding chip carrier or an active metal brazing chip carrier (not shown). The dielectric is sandwiched between the upper and lower metal layer in the stack and hence electrically isolates the upper and the lower layers from each other. The lower metal layer is fixed inside the cavity 108. This may be done in the process and thus simultaneously to mounting the semiconductor die 104 inside the cavity 106. The first end of the electrical conductor 136 is fixed, e.g. bonded to the upper metal layer of the stack.

In some examples, it is also possible to fill the cavity 108 with a potting material and the first end of the electrical conductor 136 is fixed inside the potting material. The potting material may comprise e.g., but not limited to epoxy, resin etc.

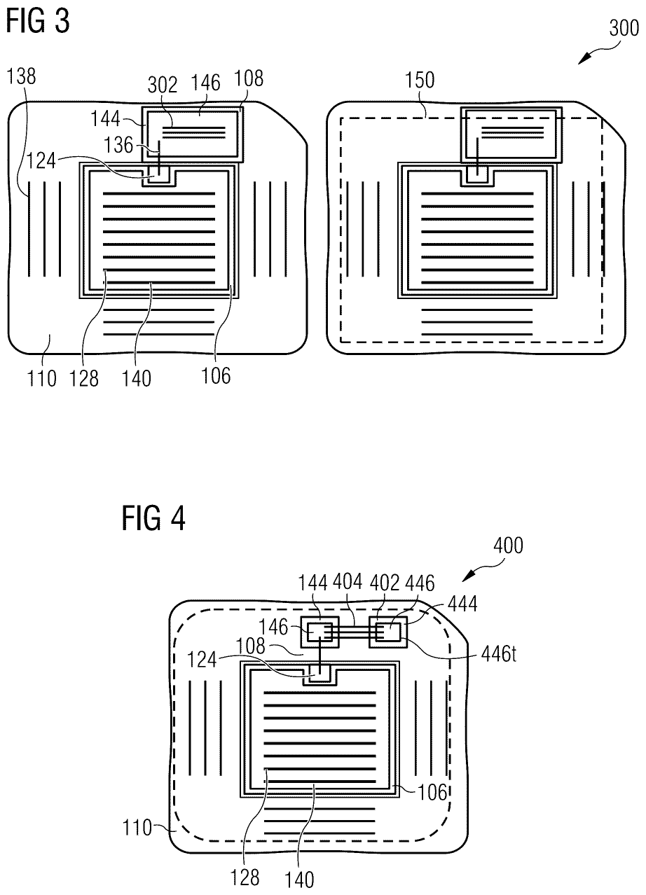

Now referring to FIG. 3, a top view of an exemplary semiconductor device 300 is illustrated with and without encapsulant 150, which may include some or all feature of the semiconductor device 100 of FIGS. 1-2 and will be discussed in regard of the differences only. The semiconductor device 300 has a plurality of electrical conductors 302 mounted over the cavity 108. The plurality of electrical conductors 302 may be arranged in an array. Both ends of each electrical conductor of the plurality of electrical conductors 302 are fixed on the top 146t of the electrically conductive structure 146 and encapsulated by the encapsulant 150. Similar to the electrical conductors 136, 138, 140, a middle section of each electrical conductor of the plurality of electrical conductors 302 is protrude from the encapsulant 150. As one end of the electrical conductor 136 and both ends of each electrical conductor of the plurality of the connections 302 are fixed on the electrically conductive structure 146 and therefore, the control pad 124 of the semiconductor die 104 can be accessed by the middle sections of the plurality of electrical conductors 302. In other words, the middle sections of the plurality of connections 302 increase the electrical contact area for electrically coupling the control pad 124 as compared to the single electrical conductor 136.

FIG. 4 shows a top view of an exemplary semiconductor device 400 which may include some or all features of the semiconductor device 300 of FIG. 3 and will be discussed in regard of the differences only. The semiconductor device 400 is characterized by a further cavity 402 on the surface 110 of the chip carrier 102. The cavity 402 has an insulating layer 444 and an electrically conductive structure 446 arranged inside the cavity 402 similar to the cavity 108. In this example, one end of each electrical conductor of a plurality of electrical conductors 404 is fixed on a top 446t of the electrically conductive structure 446 whereas another end of each electrical conductor of the plurality of electrical conductors 404 is fixed on the top 146t of the electrically conductive structure 146.

FIG. 5 shows a top view of an exemplary semiconductor device 500 which may include some or all features of the semiconductor device 100 of FIG. 1 and will be discussed in regard of the differences only. The chip carrier 102 has a further cavity 502 on the surface 110 of the chip carrier 102 with an insulating layer 544 and an electrically conductive structure 546 similar to the cavity 108. The electrical conductor 140 further extends between the load pad 128 of the semiconductor die 104 and the cavity 502. In particular, one end of the electrical conductor 140 is fixed on the load pad 128 of the semiconductor die 104 while another end of the electrical conductor 140 is fixed to a top 546t of the electrically conductive structure 546. Both ends of the electrical conductor 140 are encapsulated by the encapsulant 150 whereas the electrically conductive structure 546 may be partially exposed from the encapsulant 150. In particular, the top 546t of the electrically conductive structure 546 may be partially exposed and the exposed part of the top 546t of the electrically conductive structure 546 may be used to test the semiconductor die 104. There can be any number of suitable electrical conductor 140.

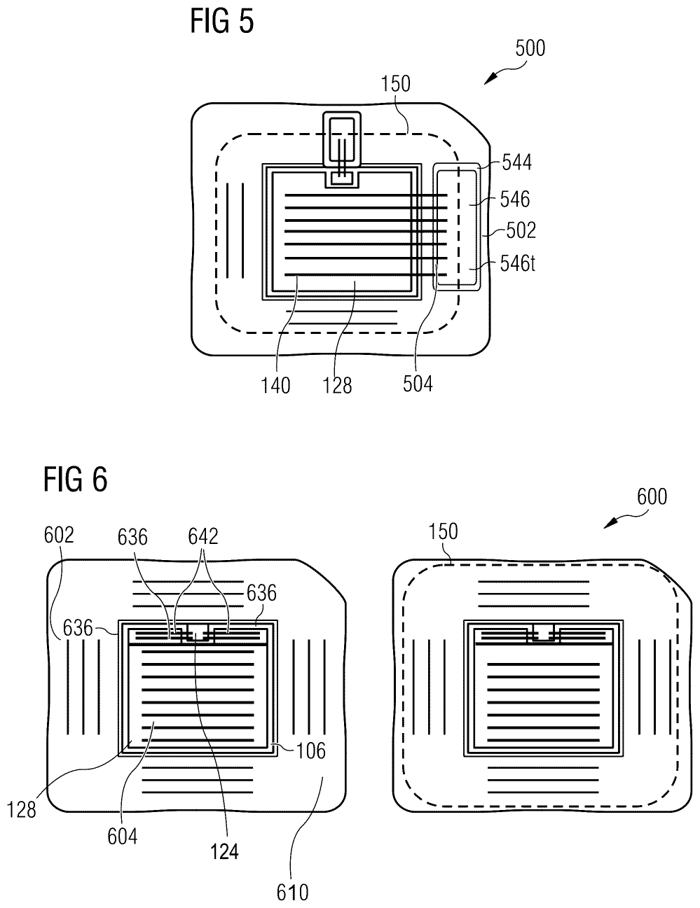

FIG. 6 shows a semiconductor device 600 which may include some or all features of the semiconductor device 100 of FIG. 1 and will be discussed in regard of the differences only. The chip carrier 602 has only one cavity 106 on the surface 610 of the chip carrier 602 and the semiconductor die 604 is mounted inside the cavity 106. In addition to the control 124 and the load pads 126, 128 the semiconductor die 604 further comprises a contact pad 642 on the upper side 120 of the semiconductor die 604 which is electrically isolated from the control 124 and the load pads 126, 128. One end of the electrical conductor 636 is fixed on the floating contact pad 642 of the semiconductor die 604 and another end of the electrical conductor 636 is fixed on the control pad 124 of the semiconductor die 604. A top section of the electrical conductor 636 is exposed from the encapsulant 150 and used for electrically coupling the control pad 124 of the semiconductor die 604 when embedded into a laminated application structure, e.g. a PCB.

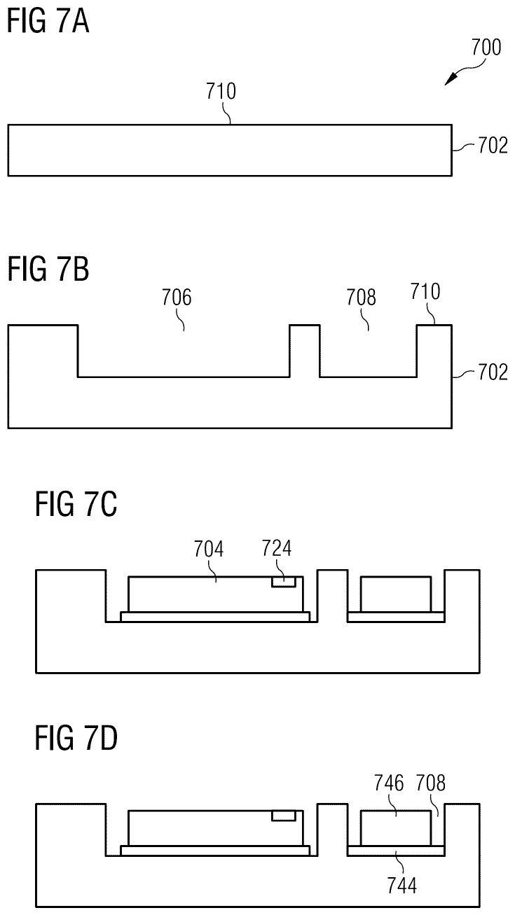

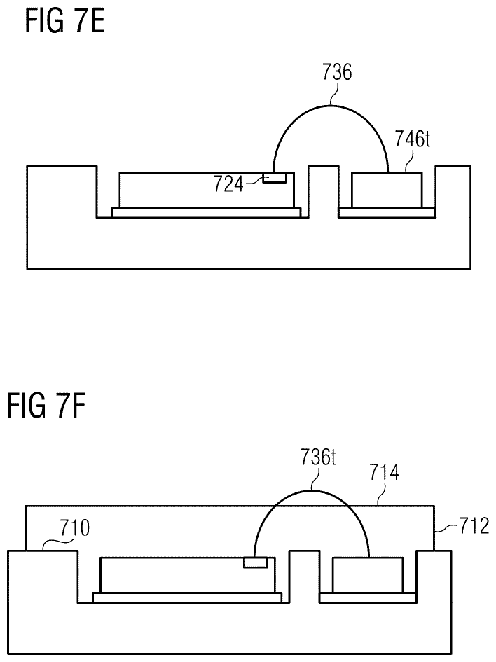

FIG. 7A-7F illustrate different steps of a method 700 for manufacturing a semiconductor device. The method 700 includes the following steps: providing a chip carrier 702 with a surface 710 (see FIG. 7A); forming a first cavity 706 and a second cavity 708 by stamping, coining or any other suitable techniques on the surface 710 of the chip carrier 702 (see FIG. 7B); mounting a semiconductor die 704 in the first cavity 706, wherein the semiconductor die 704 comprises a patterned top metallization layer comprising a first electrical contact pad 724 (see FIG. 7C); arranging an insulating layer 744 inside the second cavity 708 and mounting an electrically conductive structure 746 inside the second cavity 708 and on the insulating layer 744, wherein the electrically conductive structure 746 is electrically isolated from the chip carrier 702 (see FIG. 7D); mounting a first electrical conductor 736 comprising a first end and a second end, wherein the first end of the first electrical conductor 736 is mounted on a top 746t of the electrically conductive structure 746 and the second end of the first electrical conductor 736 is mounted on the first electrical contact pad 724 of the semiconductor die 704 (see FIG. 7E); and encapsulating the semiconductor die 704, parts of the chip carrier 702 and both ends of the first electrical conductor 736 by an encapsulant 712 and a middle section 736t of the first electrical conductor 736 is exposed from an upper surface 714 of the encapsulant opposite to the surface 710 of the chip carrier 702 (see FIG. 7F).

The semiconductor die may, for example, be configured as power MISFETs (Metal Insulator Semiconductor Field Effect Transistors), power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), power bipolar transistors or power diodes such as, e.g. PIN diodes or Schottky diodes.

The semiconductor die may be manufactured from specific semiconductor material such as, for example, Si, SiC, SiGe, GaAs, GaN, AlGaN, InGaAs, InAlAs, etc., and, furthermore, may contain inorganic and/or organic materials that are not semiconductors. The semiconductor die may be of different types and may be manufactured by different technologies.

The encapsulant may comprise any fillerless plastic or non-conducting material and may at least partly define the shape of the semiconductor device. The encapsulant may be an and may comprise or be a thermoset material or a thermoplastic material or a polymer or a mold compound without filler particles. Various techniques such as, e.g. compression molding, injection molding, powder molding, liquid molding, transfer molding or film-assisted molding (FAM) may be used to form the encapsulant.

The following examples pertain to further aspects of the disclosure.

Example 1 discloses a semiconductor device comprising: a chip carrier comprising a first cavity and a second cavity; a semiconductor die mounted in the first cavity, wherein the semiconductor die comprises a patterned top metallization layer comprising a first electrical contact pad; an insulating layer arranged inside the second cavity; a first electrical conductor comprising a first end and a second end, wherein the first end of the first electrical conductor is arranged over the insulating layer and the second end of the first electrical conductor is electrically coupled to the first electrical contact pad of the semiconductor die; and an encapsulant encapsulating the semiconductor die, both ends of the first electrical conductor and parts of the chip carrier.

Example 2 discloses the semiconductor device according to example 1, wherein a middle section of the first electrical conductor between the first and the second end protrudes from the encapsulant.

Example 3 discloses the semiconductor device according to example 2, wherein the encapsulant is a fillerless encapsulant and has a thickness in a range of μm-μm, wherein the thickness of the encapsulant is measured between the first electrical contact pad of the semiconductor die and a top surface of the encapsulant in a direction vertical to the first electrical contact pad of the semiconductor die.

Example 4 discloses the semiconductor device, according to example 3, wherein an electrically conductive structure is arranged inside the second cavity and on a top of the insulating layer such that the electrically conductive structure inside the second cavity is electrically isolated from the second cavity and wherein the first end of the first electrical conductor is fixed on the electrically conductive structure.

Example 5 discloses the semiconductor device, according to example 4, further comprising a second electrical conductor, comprising a first end and a second end, and wherein a middle section of the second electrical conductor, between the first and the second end of the second electrical conductor, protrudes from the encapsulant, wherein a first end of the second electrical conductor, is fixed on the electrically conductive structure.

Example 6 discloses the semiconductor device according to example 5, wherein the second end of the second electrical conductor is fixed on the electrically conductive structure and wherein both ends of the second electrical conductor are encapsulated by the encapsulant.

Example 7 discloses the semiconductor device according to example 5, wherein the chip carrier further comprises a third cavity, wherein an insulating layer is arranged inside the third cavity and an electrically conductive structure is fixed inside the third cavity and on a top of the insulating layer, wherein the second end of the second electrical conductor is fixed on the electrically conductive structure and wherein both ends of the second electrical conductor are encapsulated by the encapsulant.

Example 8 discloses the semiconductor device according to any preceding example, further comprises: an additional cavity on the chip carrier and an additional electrical conductor, wherein the additional cavity comprises an insulating layer arranged inside the additional cavity and an electrically conductive structure is fixed inside the additional cavity and on a top of the insulating layer, wherein the semiconductor die comprises a further patterned top metallization layer comprising a second electrical contact pad, wherein a first end of the additional electrical conductor is electrically coupled to the second electrical contact pad of the semiconductor die, and a second end of the additional electrical conductor is fixed on the electrically conductive structure, wherein both ends of the additional electrical conductor are encapsulated by the encapsulant.

Example 9 discloses a semiconductor device comprising: a chip carrier comprising a first cavity; a semiconductor die mounted inside the first cavity, wherein the semiconductor die comprises a patterned top metallization layer including a first electrical contact pad and a contact pad; a first electrical conductor, wherein a first end of the first electrical conductor is fixed on the floating contact pad of the semiconductor die and a second end of the first electrical conductor is electrically coupled to the first electrical contact pad of the semiconductor die; and an encapsulant encapsulating the semiconductor die and both ends of the first electrical conductor and wherein the first electrical conductor is partially exposed from a top surface of the encapsulant.

Example 10 discloses a method for manufacturing a semiconductor device, the method comprising: providing a chip carrier, forming a first cavity and a second cavity a surface of the chip carrier; mounting a semiconductor die in the first cavity, wherein the semiconductor die comprises a patterned top metallization layer comprising a first electrical contact pad; arranging an insulating layer inside the second cavity; mounting a first electrical conductor comprising a first end and a second end, wherein the first end of the first electrical conductor is mounted over the insulating layer and the second end of the first electrical conductor is mounted on the first electrical contact pad of the semiconductor die; and encapsulating the semiconductor die and both ends of the first electrical conductor by an encapsulant.

Example 11 discloses the method according to example 10, wherein the first end of the first electrical conductor is mounted over the insulating layer comprises mounting the first end of the first electrical conductor on an electrically conductive structure inside the second cavity, wherein the electrically conductive structure is electrically isolated from the second cavity.

Example 12 discloses the method according to example 10, wherein film assisted molding is used to partially expose the first electrical conductor from a top surface of the encapsulant.

Example 13 discloses the method according to example 11, wherein the encapsulating comprises compression molding or transfer molding over the semiconductor die in a molding cavity, wherein the molding cavity is configured such that the first electrical conductor is partially exposed from the encapsulant.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a chip carrier comprising a first cavity and a second cavity;
a semiconductor die mounted in the first cavity, wherein the semiconductor die comprises a patterned top metallization layer comprising a first electrical contact pad;
an insulating layer arranged inside the second cavity;
a first electrical conductor comprising a first end and a second end, wherein the first end of the first electrical conductor is arranged over the insulating layer and the second end of the first electrical conductor is electrically coupled to the first electrical contact pad of the semiconductor die; and
an encapsulant encapsulating the semiconductor die, both ends of the first electrical conductor, and parts of the chip carrier.

2. The semiconductor device of claim 1, wherein a middle section of the first electrical conductor between the first and the second end protrudes from the encapsulant.

3. The semiconductor device of claim 2, wherein the encapsulant is a fillerless encapsulant and has a thickness in a range of 70 μm to 100 μm, and wherein the thickness of the encapsulant is measured between the first electrical contact pad of the semiconductor die and a top surface of the encapsulant in a direction vertical to the first electrical contact pad of the semiconductor die.

4. The semiconductor device of claim 3, further comprising:
an electrically conductive structure arranged inside the second cavity and on a top of the insulating layer such that the electrically conductive structure is electrically isolated from the second cavity,
wherein the first end of the first electrical conductor is fixed on the electrically conductive structure.

5. The semiconductor device of claim 4, further comprising:
a second electrical conductor comprising a first end and a second end,
wherein a middle section of the second electrical conductor between the first and the second end of the second electrical conductor protrudes from the encapsulant,
wherein a first end of the second electrical conductor is fixed on the electrically conductive structure.

6. The semiconductor device of claim 5, wherein the second end of the second electrical conductor is fixed on the electrically conductive structure, and wherein both ends of the second electrical conductor are encapsulated by the encapsulant.

7. The semiconductor device of claim 5, wherein the chip carrier further comprises a third cavity, wherein an insulating layer is arranged inside the third cavity and an electrically conductive structure is fixed inside the third cavity and on a top of the insulating layer inside the third cavity, wherein the second end of the second electrical conductor is fixed on the electrically conductive structure, and wherein both ends of the second electrical conductor are encapsulated by the encapsulant.

8. The semiconductor device of claim 1, further comprising:
an additional cavity on the chip carrier; and
an additional electrical conductor,
wherein the additional cavity comprises an insulating layer arranged inside the additional cavity and an electrically conductive structure is fixed inside the additional cavity and on a top of the insulating layer,
wherein the semiconductor die comprises a further patterned top metallization layer comprising a second electrical contact pad,
wherein a first end of the additional electrical conductor is electrically coupled to the second electrical contact pad of the semiconductor die and a second end of the additional electrical conductor is fixed on the electrically conductive structure,
wherein both ends of the additional electrical conductor are encapsulated by the encapsulant.

9. A semiconductor device, comprising:
a chip carrier comprising a first cavity;
a semiconductor die mounted inside the first cavity, wherein the semiconductor die comprises a patterned top metallization layer including a first electrical contact pad and a floating contact pad;
a first electrical conductor, wherein a first end of the first electrical conductor is fixed on the floating contact pad of the semiconductor die and a second end of the first electrical conductor is electrically coupled to the first electrical contact pad of the semiconductor die; and
an encapsulant encapsulating the semiconductor die and both ends of the first electrical conductor, wherein the first electrical conductor is partially exposed from a top surface of the encapsulant.

10. A method for manufacturing a semiconductor device, the method comprising:
providing a chip carrier;
forming a first cavity and a second cavity on a surface of the chip carrier;
mounting a semiconductor die in the first cavity, wherein the semiconductor die comprises a patterned top metallization layer comprising a first electrical contact pad;
arranging an insulating layer inside the second cavity;
mounting a first electrical conductor such that a first end of the first electrical conductor is mounted over the insulating layer and a second end of the first electrical conductor is mounted on the first electrical contact pad of the semiconductor die; and
encapsulating the semiconductor die and both ends of the first electrical conductor by an encapsulant.

11. The method of claim 10, wherein mounting the first electrical conductor such that the first end of the first electrical conductor is mounted over the insulating layer comprises mounting the first end of the first electrical conductor on an electrically conductive structure inside the second cavity, wherein the electrically conductive structure is electrically isolated from the second cavity.

12. The method of claim 10, further comprising:
using film assisted molding to partially expose the first electrical conductor from a top surface of the encapsulant.

13. The method of claim 10, wherein the encapsulating comprises compression molding or transfer molding over the semiconductor die in a molding cavity, and wherein the molding cavity is configured such that the first electrical conductor is partially exposed from the encapsulant.
